(19) United States
(12) Patent Application Publication
(10) Pub. No.: US 2007/0148831 A1
(43) Pub. Date: Jun. 28, 2007

(54) THIN FILM TRANSISTOR DEVICE, METHOD FOR MANUFACTURING THE SAME AND DISPLAY APPARATUS HAVING THE SAME

(75) Inventors: Hitoshi NAGATA, Tokyo (JP); Yasuyoshi Itoh, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/562,258

(22) Filed: Nov. 21, 2006

(30) Foreign Application Priority Data
Dec. 23, 2005 (JP) 2005-371166

(51) Int. Cl. H01L 21/84; H01L 21/00

(52) U.S. Cl. 438/149

(57) ABSTRACT

A thin film transistor device includes: an island shaped semiconductor layer; a metal film that covers at least a part of a source region and a drain region of the semiconductor layer; a gate insulating film that covers the semiconductor layer and the metal film; an interlayer insulating film that covers the gate insulating film; and a signal wire that lies on the interlayer insulating film. The gate insulating film and the interlayer insulating film are formed with contact hole that reaches the metal film. The signal wire is connected to the metal film through the contact hole.

### BACKGROUND OF THE INVENTION

1. Field of the Invention

The present invention relates to a thin film transistor (TFT) device for use in an electro-optic display apparatus based on an active matrix system, particularly in a liquid crystal display apparatus or an organic electroluminescence (EL) type display apparatus, and a method for manufacturing the TFT device.

2. Description of the Related Art

In recent years, thin-profile display apparatus using TFTs, such as liquid crystal display apparatus or EL display apparatus, have been developed. Further, attention has been paid to TFTs using polysilicon as a material of an active region for the following reasons. That is, a high-definition panel can be formed as compared with a panel heretofore formed out of TFTs using amorphous silicon. A driving circuit region and a pixel region can be formed integrally. The cost of driving circuit chips or the cost of mounting the chips is dispensable. Thus, the manufacturing cost can be reduced.

TFT structure is classified into stagger type and coplanar type. For polysilicon TFTs, the coplanar type is widely used because a high-temperature silicon crystallization step can be carried out at the beginning of a process of manufacturing the TFTs. A general structure of a coplanar type polysilicon TFT will be described below together with its manufacturing process. The method for manufacturing a coplanar type polysilicon TFT is generally as follows. That is, an insulating film serving as an undercoat is formed on a glass substrate. A polysilicon film of 50 to 100 nm thick is formed on the insulating film, and patterned to form a channel portion of the TFT. In this event, attention may be paid to the polysilicon film which lies as a lower layer. That is, the polysilicon film may be used as a conductive film other than the channel portion. For example, separately from an active region or on the extension of the active region, the polysilicon film may be patterned and made conductive to serve as a lower electrode of a storage capacitor.

After the polysilicon film is patterned, a gate insulating film made of a silicon oxide film or the like is formed to cover the polysilicon film, and a gate electrode and an upper electrode of the storage capacitor are formed further thereon. After that, an interlayer insulating film is formed. Then, contact holes 500 to 600 nm deep are provided in the gate insulating film and the interlayer insulating film so as to reach the polysilicon film. Signal wires made of a metal film are formed so as to be connected to the polysilicon film through the contact holes. After that, an upper insulating film is further formed, and a pixel electrode is formed so as to be connected to one of the signal wires through a contact hole provided in the upper insulating film. Thus, a TFT device including a pixel electrode of an active matrix is completed.

When a TFT device having a configuration where a polysilicon film is disposed as a lower layer is manufactured thus, it is necessary to take some points into account. First, when a polysilicon film is used as a lower electrode of a storage capacitor, the specific resistance of the polysilicon film is required to be made low enough to serve as the lower electrode. It is therefore necessary to increase the dose of impurities with which the polysilicon film should be doped. However, increase in dose leads to increase in damage on the gate insulating film. It is therefore necessary to use a method to increase the dose to the polysilicon film while suppressing the damage. As a solution to this problem, for example, JP-A-2001-296550 (see FIG. 5) discloses a method in which any portion other than the storage capacitor is masked when the polysilicon film serving as the lower electrode of the storage capacitor is doped with impurities.

Secondly, when a contact hole to reach the polysilicon film which is a lower layer is opened in an insulating film including the interlayer insulating film and the gate insulating film, an etching process is required not to etch through the polysilicon film which should serve as the bottom portion of the contact hole. When the polysilicon film is etched through, the polysilicon film is absent from the bottom portion of the contact hole. As a result, a place that can be electrically connected is only a section of the polysilicon film exposed to the inner wall surface of the contact hole. Thus, the connection resistance increases. The total film thickness of the insulating film including the interlayer insulating film and the gate insulating film reaches about 600 nm. On the other hand, the film thickness of the polysilicon film lying under the insulating film is only about 50 to 100 nm. When uniformity or controllability in the process is enhanced, it is very difficult to etch the insulating film perfectly all over the contact holes without etching through the polysilicon film. To solve this problem, it is essential to secure a high etching selectivity of the insulating film to the polysilicon film in such an etching process. In the etching with a high regard for only the etching selectivity, contact holes can be opened in good condition without etching through the polysilicon film. Generally, however, such etching leads to reduction in etching rate. It takes much time to open the insulating film which is very thick. Thus, there arises a problem that the productivity deteriorates on a large scale. As a solution to such a trade-off, JP-A-2001-264813 (see FIG. 1) discloses a technique in which etching is performed in two stages so as to secure both the selectivity and the mass productivity.

JP-A-10-170952 (see FIG. 8) discloses a method in which a silicon film, a silicide film or a metal film is formed under the polysilicon film so as to expand the margin in the etching process and thereby prevent the polysilicon film from being etched through or the etching from running short.

### SUMMARY OF THE INVENTION

When a polysilicon film is used as a lower electrode of a storage capacitor, it is necessary to dope the polysilicon film with a high-concentration dopant. To this end, a long process time is required. The doping process is a process with low mass productivity. The doping inevitably leads to damage on an insulating film serving as a capacitance of the storage capacitor, causing deterioration in storage capacitor. Further, as long as the lower electrode is formed out of the polysilicon film, there is a limit in reduction of resistance only by the concentration of the dopant. There is a problem that the lower electrode itself has a capacitance component which resists desired properties. In addition to the problem caused by the capacitance component, there is another problem that a resistance component in series with the storage capacitor increases due to the polysilicon film elongated to the lower electrode of the storage capacitor.

In addition, the manner in which etching is carried out in two stages to open contact holes is not suitable for mass productivity. Further, the method in which a polysilicon film has an undercoat separately formed of another silicon film has a limited effect in view from selectivity and may not completely cope with variation in terms of the thickness of the interlayer insulating film and the in-plane distribution of the etching rate. If an opening of a contact hole is not formed in good condition, electric conduction between a signal wire and a doped region of the polysilicon film will be insufficient, or signal transmission between the doped region of the polysilicon film and a pixel electrode portion will not be attained in good condition. Thus, a defect on display will be brought about.

The present invention has been made in view of above circumstances and provides a TFT and a manufacturing method thereof to solve the foregoing problems caused by a thin polysilicon film serving as a conductive film which is the lowest layer of the TFT. That is, according to an embodiment of the invention, there is provided a TFT and a manufacturing method in which damage given to an insulating film by doping is suppressed to a minimum so as to secure excellent mass productivity, and the resistance of a lower electrode of a storage capacitor can be reduced easily so as to contribute to improvement in properties. According to another embodiment of the invention, there is provided a TFT and a manufacturing method to attain excellent electric conduction between a signal wire of a TFT and a doped region of a thin polysilicon film serving as the conductive film which is the lowest layer. According to a further embodiment of the invention, there is provided a TFT and a manufacturing method to reduce a total connection resistance between the doped region of the polysilicon film and a pixel electrode in which resistance has especially great influence on display.

According to an aspect of the invention, there is provided a thin film transistor device including: a substrate; an island shaped semiconductor layer formed on the substrate, the semiconductor layer including a source region and a drain region; a metal film that covers at least a part of the source region and the drain region; a gate insulating film that covers the semiconductor layer and the metal film; an interlayer insulating film that covers the gate insulating film; and a signal wire that lies on the interlayer insulating film. The gate insulating film and the interlayer insulating film are formed with contact hole that reaches the metal film. The signal wire is connected to the metal film through the contact hole.

According to the above configuration, the metal film is formed to have a portion that coats a doped region of a thin polysilicon film serving as a conductive film and that overlaps just under a contact hole. Accordingly, there is an effect that the connection resistance with an upper-layer electrode through the contact hole can be reduced, so that excellent display properties can be obtained. In addition, a lower electrode of a storage capacitor can be formed out of the metal film having low resistance. Accordingly, there is an effect that deterioration of an insulating layer caused by doping can be suppressed, and the mass productivity can be secured, while a stable capacitance can be formed so that the display properties can be improved.

### BRIEF DESCRIPTION OF THE DRAWINGS

FIG. 1 is a sectional view showing a sectional structure of a thin film transistor (TFT) device according to Embodiment 1 of the invention.

FIGS. 2A to 2D are sectional process views for explaining steps of a method for manufacturing the thin film transistor (TFT) device according to Embodiment 1 of the invention.

FIG. 3 is a sectional view showing a sectional structure of a thin film transistor (TFT) device according to Embodiment 2 of the invention.

FIG. 4 is a sectional view showing a sectional structure of a thin film transistor (TFT) device according to Embodiment 3 of the invention.

FIG. 5 is a sectional view showing a sectional structure which is used for making comparison with that of the thin film transistor (TFT) device according to Embodiment 3 of the invention.

### DETAILED DESCRIPTION OF THE INVENTION

A TFT device according to embodiments of the invention and a method for manufacturing the same will be described below with reference to the drawings.

### Embodiment 1

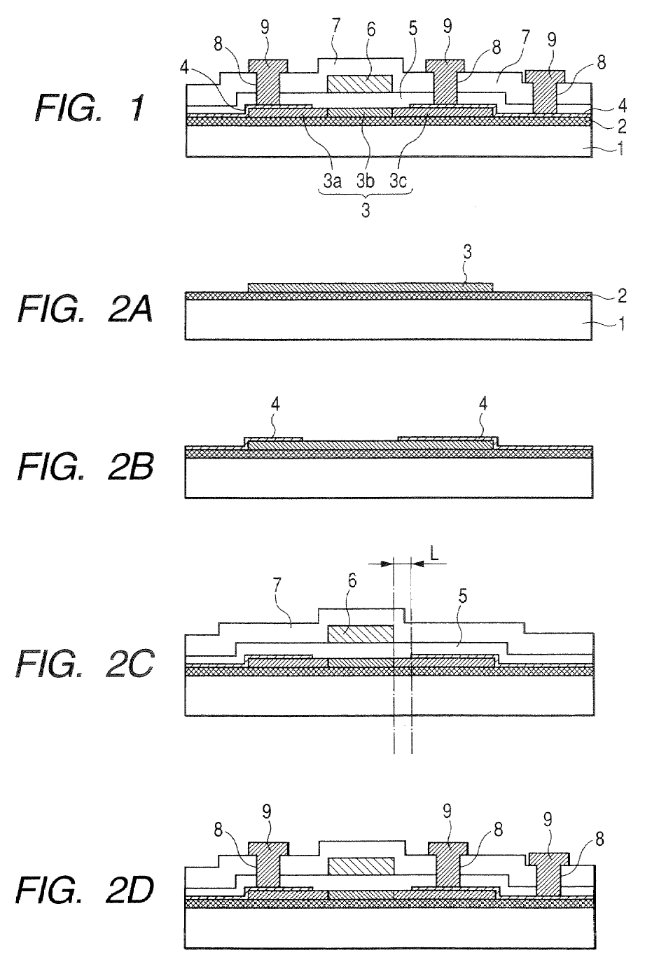

FIG. 1 shows a sectional view of a substrate for a liquid crystal panel according to Embodiment 1.

In FIG. 1, a polysilicon film 3 formed on a protective insulating film 2 on a glass substrate 1 has a source region 3a, a drain region 3c and a channel region 3b. A metal film 4 is provided to cover the source region 3a and the drain region 3c. A gate insulating film 5 is formed to cover the protective insulating film 2, the polysilicon film 3 and the metal film 4. A gate electrode 6 is formed on top of the gate insulating film 5 so as to be located above the channel region 3b. Further the gate insulating film 5 and the gate electrode 6 are coated with an interlayer insulating film 7 made of SiO₂ or the like. Signal wires 9 are provided on top of the interlayer insulating film 7 so as to be connected to the metal film 4 on the source region 3a and the drain region 3c through contact holes 8 provided in the interlayer insulating film 7 and the gate insulating film 5.

In the TFT device shown in FIG. 1, the metal film 4 lies in the bottom portions of the contact holes 8. There is no fear that the polysilicon film 3 is etched through when the contact holes 8 are opened by etching. The signal wires 9 can be connected to the source region 3a and the drain region 3c through the metal film 4 with low resistance. Thus, the metal film 4 can also contribute to improvement in display properties.

A method for manufacturing a TFT according to the Embodiment 1 as shown in FIG. 1 will be described below with reference to FIGS. 2A to 2D. In FIG. 2A, by CVD or the like, a protective insulating film 2 made of an insulating film such as a silicon oxide film or a silicon nitride film is formed on a surface of a substrate 1 such as a quartz substrate or a glass substrate, and a polysilicon film of 50 to 200 nm thick is formed. The polysilicon film is patterned by etching so as to form an island-like polysilicon film 3 as a semiconductor layer.

In a subsequent step, a channel region 3b, a source region 3a and a drain region 3c of the TFT will be built in the polysilicon film 3. This step will be described later. In FIG. 2B, a metal film 4 is formed by a sputtering method or the like, and patterned. In this event, the regions where the metal film 4 survives after the patterning are regions which will be located under contact holes 8 as will be described later, and which will be located above the source region 3a and the drain region 3c as will be described later. If the metal film 4 is too thick, it will be difficult to dope the polysilicon film 3 just under the metal film 4 with impurities as will be described later. For this reason, the metal film 4 is preferably not thicker than 100 nm. Normally in order to improve the performance of the TFT as to threshold values or mobility thereof, heat treatment at 350 to 450° C. may be effective in a subsequent step. In order to facilitate the heat treatment, it is desired to use a high-melting metal such as Ti, Ta, W, Mo, etc. or a conductive metallic compound such as TiN, TaN, HfN, WN, MoN, ZrN, VN, NbN, TiB₂, ZrB₂, HfB₂, VB₂, NbB₂ and TaB₂ as the metal film.

In FIG. 2C, a gate insulating film 5 having a thickness of 70 to 150 nm is formed to cover the protective insulating film 2, the polysilicon film 3 and the metal film 4 by a CVD method or the like. After that, a metal film to be a gate electrode of the TFT is formed with a thickness of 100 to 500 nm on the gate insulating film 5 by a sputtering method or the like. Then, the metal film is patterned by etching. Thus, a gate electrode 6 is formed to overlap the channel region 3b. Then, using the gate electrode 6 as a mask, regions serving as the source region 3a and the drain region 3c are formed in an active layer of the TFT by ion implantation of impurities (e.g. phosphorous) so as to be self-aligned. In this event, the impurities are not introduced under the gate electrode 6. The portion where the impurities are not introduced is left as the channel region 3b.

Particularly it is desired that a distance L between an end portion of the gate electrode 6 and an end portion of the metal film 4 in the drain region is set to keep a distance expressed by L≧1 μm in order to prevent leakage of the TFT. Next, an interlayer insulating film 7 such as a silicon oxide film is formed with a thickness of 300 to 700 nm on the gate electrode 6 and the gate insulating film 5 by a CVD method or the like.

In FIG. 2D, for the source region 3a, the drain region 3c and the metal film 4 used for wiring, contact holes 8 are formed in the interlayer insulating film 7 and the gate insulating film 5 by a dry etching method. In this event, reactive ion etching or chemical dry etching using CF₄ or SF₆ as etching gas, plasma etching, etc. can be used as anisotropic dry etching. The mixing ratio of the etching gases maybe changed to change the etching rate. The etching selectivity of the polysilicon film to the silicon oxide film in normal chemical dry etching or plasma etching is at least 10. The etching rate of the polysilicon film is higher. Such etching does not stop in the surface of the polysilicon film, but etches through the polysilicon film easily. In the reactive ion etching, the etching selectivity can be inverted, but the etching rates are decelerated. In addition, post-treatment may be required because a residue adheres to the etched surface. In the present invention, the metal film 4 is formed as a layer covering the source region 3a and the drain region 3c. Accordingly, the metal film 4 lies in the bottoms of the contact holes 8. The etching selectivity of a film of a metal material to a silicon oxide film can be generally made lower than 1 comparatively easily. Thus, there is an effect that excellent connections can be obtained while preventing the polysilicon film from being penetrated by etching.

After that, a low-resistance conductive film of aluminum or the like is formed all over the surface by a sputtering method, and patterned. Thus, signal wires 9 are connected to the source region 3a and the drain region 3c through the contact holes 8.

In Embodiment 1 of the invention, a metal film is formed on a polysilicon film correspondingly to source and drain regions of a TFT. Thus, the polysilicon film can be prevented from being penetrated by etching for opening contact holes. It is therefore possible to obtain excellent connections of the polysilicon film with upper-layer electrodes.

### Embodiment 2

In Embodiment 1 of the invention, due to a metal film formed as a layer covering a thin polysilicon film, it is possible to solve one of problems caused by use of the thin polysilicon film. That is, it is possible to prevent the polysilicon film from being etched through when contact holes are opened. As a result, it is possible to suppress increase in connection resistance between a drain region and a signal wire. According to Embodiment 2 of the invention, there is provided another effect.

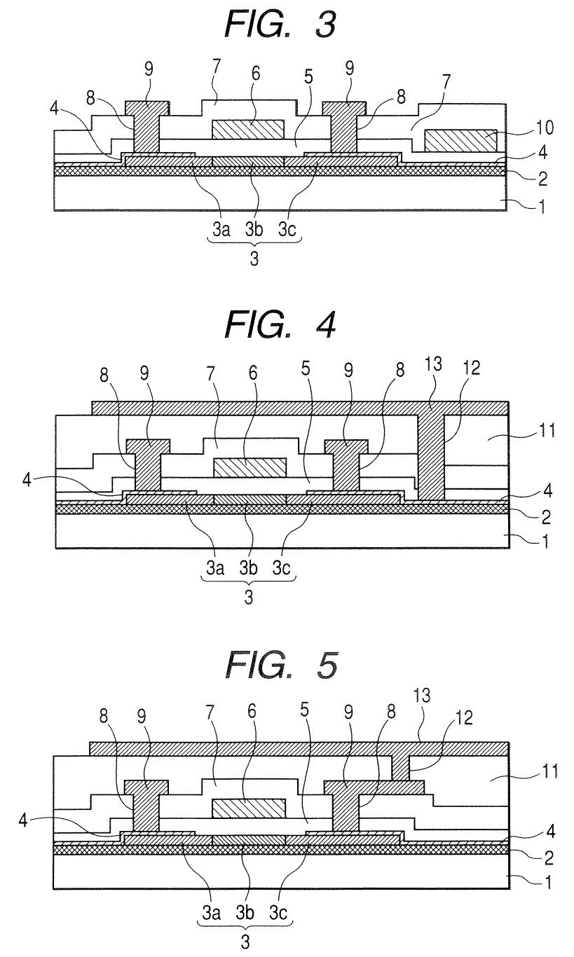

FIG. 3 shows a sectional view of a TFT device according to Embodiment 2 of the invention. In FIG. 3, constituent parts the same as those in Embodiment 1 shown in FIG. 1 are referenced correspondingly. The following points are not shown in FIG. 1. That is, there is provided an upper electrode 10 of a storage capacitor, which is formed in the same layer as the gate electrode 6, and the metal film 4 is also used as a lower electrode of the storage capacitor opposed to the upper electrode 10.

A method for manufacturing the TFT device according to Embodiment 2 will be described below. Steps of the manufacturing method the same as those in Embodiment 1 will be omitted. First, in FIG. 2B, when the metal film 4 is patterned, the metal film 4 extends to a region corresponding to the lower electrode of the storage capacitor in Embodiment 2. After that, the gate electrode 6 and the upper electrode 10 of the storage capacitor are formed by patterning on the gate insulating film 5 formed in the same manner as in Embodiment 1, so as to overlap the regions where the metal film has been formed. When the lower electrode of the storage capacitor is formed only out of the polysilicon film 3 in a normal manner, the lower electrode has to be doped with impurities with a high dose before formation of the upper electrode 10 of the storage capacitor, in order to reduce the specific resistance of the lower electrode. In Embodiment 2, however, such a step is not required due to the extension of the metal film 4. After that, the interlayer insulating film 7, the contact holes 8 and the signal wires 9 are formed in the same manner as in Embodiment 1. Thus, a TFT device as shown in FIG. 3 is completed.

The gate insulating film 5 can be used as a dielectric film between the upper electrode 10 and the lower electrode of the storage capacitor as in Embodiment 2. In this case, there is an effect that the number of steps does not have to be increased, but the invention is not limited to this manner. The dielectric film may be formed separately. When a highly dielectric insulating film such as a silicon nitride film is used as the dielectric film, there is an effect that the capacitance value of the storage capacitor can be increased.

The step of doping the lower electrode with impurities with a high dose for achievement of lower resistance required as the lower electrode has to be carried out when only a polysilicon film is provided as in the related art. In Embodiment 2 of the invention, however, due to the lower electrode of the storage capacitor formed out of a metal film, the impurities doping step is dispensable. It is therefore possible to shorten the manufacturing process on a large scale. In addition, the resistance can be made lower than that when the polysilicon film is used. Thus, there is an effect that the resistance in series with the storage capacitor is reduced.

### Embodiment 3

In Embodiment 1 of the invention, due to a metal film formed as a layer covering a thin polysilicon film, it is possible to solve one of problems caused by use of the thin polysilicon film. That is, it is possible to prevent the polysilicon film from being etched through when contact holes are opened. As a result, it is possible to suppress increase in connection resistance between a drain region and a signal wire. According to Embodiment 3 of the invention, the total connection resistance between a drain region and a pixel electrode is further suppressed from increasing compared with Embodiment 1.

A TFT device according to Embodiment 3 of the invention will be described below with reference to FIG. 4. In FIG. 4, constituent parts the same as those in Embodiment 1 shown in FIG. 1 are referenced correspondingly. The following points are added to the configuration of FIG. 1. That is, an upper insulating film 11 is formed to cover the TFT shown in FIG. 1, a pixel electrode 13 is formed as a layer covering the upper insulating film 11, and an upper contact hole 12 opened in the upper insulating film 11, the interlayer insulating film 7 and the gate insulating film 5 is formed to connect the pixel electrode 13 with the metal film 4.

A method for manufacturing the TFT device according to Embodiment 3 will be described below. Steps of the manufacturing method the same as those in Embodiment 1 will be omitted. First, in the structure shown in FIG. 2C, contact holes 8 are formed to reach the metal film 4 on the source region 3a and the metal film 4 on the drain region 3c respectively in the same manner in Embodiment 1. Signal wires 9 are formed to be connected to the metal film 4. Further, an upper insulating film 11 is formed to cover the signal wires 9 and the interlayer insulating film 7. (not shown) The upper insulating film 11 may be formed by forming a silicon oxide film or a silicon nitride film by a method such as CVD, by applying a resin film, or by forming a lamination of the silicon dioxide film, the silicon nitride film or the resin film. After that, on the metal film 4 extending from the top of the drain region 3c, an upper contact hole 12 is opened through the upper insulating film 11, the interlayer insulating film 7 and the gate insulating film 5. After that, a pixel electrode 13 is formed on the upper insulating film 11 so as to be connected with the metal film 4 exposed in the bottom of the opening. Thus, a TFT structure shown in FIG. 4 is formed. For example, a film formed out of a transparent conductive material such as ITO or a metal material such as Al by a sputtering method and then patterned is used as the pixel electrode 13.

Here, the insulating film when the upper contact hole 12 is opened is thicker than that when the contact holes 8 are opened in Embodiment 1. However, due to extension of the metal film 4, the insulating film can be removed while preventing the polysilicon film 3 from being penetrated by etching. Thus, the pixel electrode 13 and the drain region 3c can be connected through the metal film 4 in good condition. Further, in Embodiment 3, the pixel electrode 13 is connected to a lower-layer laminated conductive film of the drain region 3c and the metal film 4 directly through the upper contact hole 12. Thus, the connection resistance can be reduced sufficiently, and the display properties can be also improved.

This effect is obvious in comparison with the sectional view of a TFT device shown in FIG. 5, where a pixel electrode 13 is added as a top layer of the TFT device according to Embodiment 1. In FIG. 5, the pixel electrode 13 is connected to a signal wire 9 through a contact hole 12, and further the signal wire 9 is connected to a metal film 4 through a contact hole 8. That is, due to the structure shown in Embodiment 3, the number of kinds of conductive layers lying between the pixel electrode 13 and the drain region 3c can be reduced from two to one. Thus, the total connection resistance can be reduced, and the display properties can be improved.

The TFT devices according to Embodiments 1 to 3 of the invention have a feature in that the polysilicon film 3 including the source region 3a and the drain region 3c has low-resistance connections to the signal wires 9 and the pixel electrode 13 through the metal film 4. Thus, the TFT devices are suitable for use in display apparatus. That is, the TFT devices according to the invention can be used in display apparatus having an active matrix type array substrate where the TFT devices are disposed near the intersection portions in which signal wires and scan lines intersect in a display region of the display apparatus.

Specifically, a liquid crystal display apparatus can be formed by bonding an array substrate provided with the TFT devices according to the invention with a color filter substrate, and injecting a liquid crystal material into the inside between the two substrates. An electroluminescent display apparatus can be formed by laminating self-luminous materials and opposed electrodes on pixel electrodes 13 on an array substrate. The TFT devices according to the invention may be used not only in a display region but also in a driving circuit located in the periphery of the display region. In this case, the TFT devices in the driving circuit can be formed concurrently with the TFT devices in the display region.

Embodiments 1 to 3 of the invention may be combined suitably, or applications or modifications can be made thereon. For example, the region where the metal film 4 is formed does not have to perfectly coincide with the region where the contact hole 8 is opened. Even when the two regions are not aligned with each other, it will go well if one of the two includes the other.

The polysilicon film 3 may be extended under the lower electrode of the storage capacitor. In this case, the metal film 4 does not have to cover the step of the polysilicon film 3. There is an effect that disconnection can be prevented.

In Embodiment 3 of the invention, the contact hole 12 may be opened in a position where the metal film 4 overlaps the source region 3a or the drain region 3c.

In Embodiment 2 of the invention, the metal film 4 on the polysilicon film 3 is formed on the source region 3a and on the drain region 3c, and further elongated to be formed as the lower electrode of the storage capacitor. However, the metal film 4 may be applied to one of those portions. In this case, the effect described in Embodiment 1 of the invention can be obtained in the portion to which the metal film 4 is applied.

Embodiments 1 to 3 of the invention were described along TFT devices where the protective insulating film 2 was formed out of a silicon oxide film or a silicon nitride film. However, the protective insulating film 2 may be a laminated film made of a silicon oxide film and a silicon nitride film. Alternatively, the protective insulating film 2 itself may be omitted. In either case, the effect of the invention is not spoilt.

The entire disclosure of Japanese Patent Application No. 2005-371166 filed on Dec. 23, 2005 including specification, claims, drawings and abstract is incorporated herein by reference in its entirety.

What is claimed is:

1. A thin film transistor device comprising:
a substrate;
an island shaped semiconductor layer formed on the substrate, the semiconductor layer including a source region and a drain region;
a metal film that covers at least a part of the source region and the drain region;
a gate insulating film that covers the semiconductor layer and the metal film;
an interlayer insulating film that covers the gate insulating film; and
a signal wire that lies on the interlayer insulating film,
wherein the gate insulating film and the interlayer insulating film are formed with contact hole that reaches the metal film, and
wherein the signal wire is connected to the metal film through the contact hole.

2. The thin film transistor device according to claim 1, further comprising:
a thin film transistor that includes the semiconductor layer, the metal film, the gate insulating film, and a gate electrode formed on the gate insulating film; and
a storage capacitor that includes a lower electrode, an insulating capacitance film and an upper electrode,
wherein the metal film extends so that a part of the metal film serves as at least a part of the lower electrode of the storage capacitor.

3. The thin film transistor device according to claim 2, wherein the semiconductor layer extends under the lower electrode of the storage capacitor.

4. The thin film transistor device according to claim 2, wherein the upper electrode of the storage capacitor is made of the same material as the gate electrode.

5. The thin film transistor device according to claim 2, wherein the insulating capacitance film of the storage capacitor is made of the same material as the gate insulating film.

6. The thin film transistor device according to claim 1, further comprising:
a thin film transistor that includes the semiconductor layer, the metal film, the gate insulating film, and a gate electrode formed on the gate insulating film;
a storage capacitor that includes a lower electrode, an insulating capacitance film and an upper electrode;
an upper insulating film that covers the thin film transistor and the storage capacitor; and
a pixel electrode that is formed on the upper insulating film,
wherein the pixel electrode is electrically connected to the metal film through a contact hole running through the upper insulating film and the insulating film under the upper insulating film.

7. The thin film transistor device according to claim 1, wherein the metal film includes a high-melting metal or a conductive metallic compound.

8. The thin film transistor device according to claim 1, wherein the metal film contains at least one selected from the group consisting of Ti, Ta, W, Mo, TiN, TaN, HfN, WN, MoN, ZrN, VN, NbN, TiB₂, ZrB₂, HfB₂, VB₂, NbB₂ and TaB₂.

9. A method for manufacturing a thin film transistor device, the method comprising:
forming an island shaped semiconductor layer on a substrate, the semiconductor layer including a source region and a drain region;
forming a metal film that is connected to the semiconductor layer and covering at least a part of the source region and the drain region; and
forming a gate insulating film covering the semiconductor layer and the metal film.

10. The method for manufacturing a thin film transistor device according to claim 9, wherein the metal film includes a high-melting metal or a conductive metallic compound.

11. The method for manufacturing a thin film transistor device according to claim 9, wherein the metal film contains at least one selected from the group consisting of Ti, Ta, W, Mo, TiN, TaN, HfN, WN, MoN, ZrN, VN, NbN, TiB₂, ZrB₂, HfB₂, VB₂, NbB₂ and TaB₂.

12. A display apparatus comprising,
a display unit; and
a thin film transistor device that drives the display unit, the thin film transistor device comprising:
a substrate;
an island shaped semiconductor layer formed on the substrate, the semiconductor layer including a source region and a drain region;
a metal film that covers at least a part of the source region and the drain region;
a gate insulating film that covers the semiconductor layer and the metal film;
an interlayer insulating film that covers the gate insulating film; and
a signal wire that lies on the interlayer insulating film,
wherein the gate insulating film and the interlayer insulating film are formed with a contact hole that reaches the metal film, and
wherein the signal wire is connected to the metal film through the contact hole.
